(19) United States
(12) Patent Application Publication
(10) Pub. No.: US 2001/0051443 A1
(43) Pub. Date: Dec. 13, 2001

(54) Defect analysis method in image sensor device

(75) Inventor: Jeong-Hoi Koo, Ichon-shi (KR)

Correspondence Address: TOWNSEND and TOWNSEND and CREW LLP, Two Embarcadero Center, 8th Floor, San Francisco, CA, 94111-3834, US

(73) Assignee: Hyundai Electronics Industries Co., Ltd.

(21) Appl. No.: 09/735,214

(22) Filed: Dec. 12, 2000

(30) Foreign Application Priority Data
Dec. 13, 1999 (KR) 1999-57237

(51) Int. Cl. G02F 1/13; H01L 21/31; H01L 21/469

(52) U.S. Cl. 438/765

(57) ABSTRACT

A method of analyzing defects arising from a plurality of photoresist-based layers formed on top of a color filter array in an image sensor is provided. The method comprises the steps of: providing a sample wafer on a passivation layer on a substrate fabricated by a predetermined process, wherein the sample array comprises, sequentially layered, a color filter array, an overcoating layer and a micro-lens, each of which is made of photoresist material; immersing the sample wafer in a hydrofluoric acid solution to etch the passivation layer and expose the back side of the color filter array; and observing defects arising from the photoresist-based layers in the back side of the color filter array.

### FIELD OF THE INVENTION

The present invention relates to a defect analysis method in an image sensor; and, more particularly, to a method for analyzing defects to be invoked from a plurality of photoresist-based layers formed on top of a passivation layer.

### DESCRIPTION OF THE PRIOR ART

As is well known, an image sensor is manufactured by processes of: a) forming a passivation layer after fabrication of a semiconductor device; b) forming a color filter array (CFA) to implement a color image on the passivation layer; c) forming an overcoating layer (OCL) for smoothness and focus adjustment on the overall surface of the CFA; and d) forming a micro-lens thereon for light focusing. Typically, the color filter array, the OCL and the micro-lens are made of a photoresist material.

After the fabrication of the semiconductor device, a defect analysis requires sampling of the semiconductor device. To do this, typical deprocessing technology is employed. Stripping each layer in order starting from the last layer deposited performs the defect analysis.

However, the deprocessing technology mentioned above fails to analyze defects in layers that come after the CFA. In other words, as previously described, since each layer formed on top of the color filter array is made of the same material (i.e., photoresist) as the CFA, it is difficult to etch the micro-lens and the OCL layer and strip them with the color filter array exposed.

Accordingly, in the prior art, an optical microscope has typically been utilized in analyzing defects in layers that come after the CFA. Unfortunately, because the micro-lens has a geometric structure in which the upper portion of the microlens is concave, the prior art technique is deficient in that it is impossible to detect defects arising from the photoresist-based layers.

In addition, the prior art technique suffers from the disadvantage that a plane observation by the optical microscope results in degraded resolution that reduces the accuracy of the defect analysis.

As mentioned above, the image sensor has a geometric structure with the micro-lens at its top and the optical microscope has limited resolution. As a result, the prior art technique is limited in that it is difficult to detect defects by using only the optical microscope without the help of the deprocessed sample. In addition, since each layer starting with the color filter array is made of photoresist, the prior art deprocessing technique fails to analyze the defects arising from the layers on top of the CFA. Accordingly, it would be desirable to provide a method of exposing a defective portion using a layer-by-layer delayering technique, and identifying a device fail mechanism (i.e. defect) and the origin of the defect through an image analysis and a sample analysis that overcomes the limitations of the prior art.

### SUMMARY OF THE INVENTION

An object of the present invention is to provide a method of analyzing defects arising from a plurality of photoresist-based layers formed on top of a color filter array (CFA) in an image sensor.

In accordance with one aspect of the present invention, there is provided a method for analyzing defects in an image sensor, comprising the following steps: a) providing a sample wafer on a passivation layer on a substrate fabricated by a predetermined process, wherein the sample array comprises, sequentially layered, a color filter array, an overcoating layer and a micro-lens , each of which is made of photoresist material; b) immersing the sample wafer in a hydrofluoric acid solution to etch the passivation layer and expose the back side of the color filter array; and c) observing defects occurring in the photoresist-based layers in the back side of the color filter array.

In accordance with another aspect of the present invention, there is provided a method of analyzing defects in an image sensor, comprising the steps of: a) providing a sample wafer on a passivation layer on a substrate fabricated by a predetermined process, wherein the sample array comprises, sequentially layered, a color filter array, an overcoating layer and a micro-lens, each of which is made of photoresist material; b) providing a dummy wafer with double-sided tape attached on one side; c) pasting a surface on which the micro-lens of the sample wafer is formed to the other side of the double-sided tape; d) immersing the sample wafer in a hydrofluoric acid solution to etch the passivation layer and expose the back side of the color filter array; and e) performing a reaction ion etching from the back side of the color filter array to a defective portion; and f) observing the defect. If there is no defect on the back side of the color filter array, but a defect is present within the color filter array or on the interface between the overcoating layer and the micro-lens, etching may be performed from the back side of the color filter array to expose the defect, according to another aspect of the present invention.

Preferably, carbon tape is used as the double-sided tape. The carbon tape comprises an electrically conducting material, which prevents charge buildup during the use of a scanning electron microscope.

As previously mentioned, the present invention provides a method of analyzing a defect on the back side of the color filter array to overcome a structural limitation of the microlens. Also, the present invention uniformly detects a defect through an etching process and observes defects in a high-resolution image analysis system such as a scanning electron microscope. Furthermore, the present invention provides a method of determining, under optimal conditions, if a pixel pattern is normal, thereby significantly enhancing reliability and shortening production time by allowing removal of the defect source once it is identified.

The above and other objects and features of the present invention will become apparent from the following description and accompanying drawings.

### BRIEF DESCRIPTION OF THE DRAWINGS

FIGS. 1 and 2 are pictorial views illustrating a sample fabrication process used in analyzing defects arising from a plurality of photoresist-based layers (i.e., a CFA, an OCL layer and a micro-lens) in an image sensor;

FIG. 3 shows photographs captured of the front and rear of the CFA using a sample fabricated by a method according to the present invention; and

FIG. 4 shows a pictorial view of various defects observed in accordance with application of a method of the present invention.

### DETAILED DESCRIPTION OF THE PREFERRED EMBODIMENTS

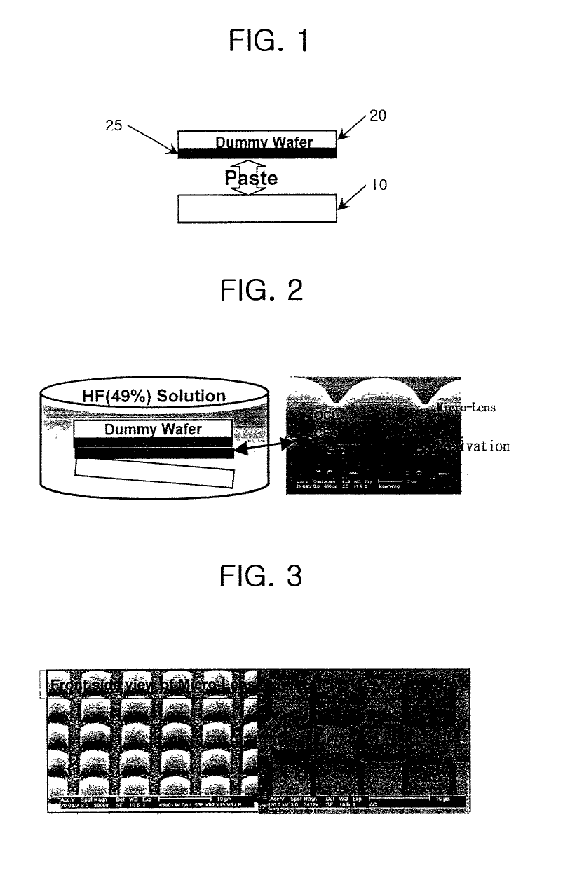

Referring to FIGS. 1 and 2, there are shown pictorial views of a sample fabrication process used to analyze defects, which may arise from a plurality of photoresist-based layers (e.g., a CFA, an OCL layer and a micro-lens) in an image sensor.

As shown in FIG. 1, sample wafer 10 has a micro-lens at its top. Sample wafer 10 is used as an analysis target as will be explained below. Next, a dummy wafer 20 to which one side of a double-sided carbon tape 25 is attached is prepared. After that, a surface on which the micro-lens of sample wafer 10 is formed is pasted to the other side of the carbon tape 25. The application of physical force to the contacted portion allows increased adhesivity of the contacted portion, thereby rendering it difficult to separate the portion by subsequent chemical processes.

Carbon tape 25 is a double-sided tape and is held fast by a chemical reaction. The present invention uses carbon tape to prevent the surface of the sample wafer from charging up due to incident electron beams, since the defects are detected in subsequent processes by using a scanning electron microscope. Furthermore, in defect analysis using the optical microscope, an effective sample fabrication is achieved by adhering the double-sided tape 25 to the top of the dummy wafer 20. Defect analysis using a scanning electron microscope requires coating dummy wafer 20 with an electrically conducting material to prevent a charging up. In this case, sputtering increases the possibility of pattern damage, therefore carbon tape 25 is most effective.

In an ensuing step shown in FIG. 2, the processing step is followed by separation of each layer formed after the CFA. That is, if the sample wafer 10 fabricated by the method described in FIG. 1 is immersed in a high purity hydrofluoric acid (for example, wt.49% HF) solution, the passivation layer made of an oxide is removed by reaction with the hydrofluoric acid. Simultaneously, the CFA and each layer deposited thereon are separated by chemical reaction with the portion of carbon tape 25 pasted to dummy wafer 20. Thus, the back side of the color filter array is exposed whereas the front side thereof is attached to the OCL layer.

In a subsequent step, the sample wafer is rinsed with acetone. Then the acetone is evaporated by heating the acetone, for example, on a hot plate. Thus, the sample wafer is dried. When a technique is used, which rinses the sample wafer with an ultra-pure water and dries it using N2 gas or the like, a crack may occur on the sample wafer due to N2 blow-off pressure. Hence, the acetone rinse and dry technique is preferred.

After the sample wafer is dried, an insulating film, such as a residual or natural oxide film may be present on the back side of the CFA. This oxide film may be removed by reaction ion etching (RIE) so that a clean back surface of the CFA may be obtained.

Next, the photoresist is etched by the RIE process to expose a portion where a defect exists. Unlike the prior art, but in accordance with the present invention, access to the flat back side of the color filter array enables the photoresist to be etched to a specific thickness using REI, thereby allowing the defective portion to be exposed. The REI is performed in, for example, an O₂ and CF₄ atmosphere, at for example, a power of about 50 Watts, with about 50 scam of O₂ and about 5 scam of CF₄. The etching is performed at a low RF power to suppress plasma damage. Then, the defect is observed under a scanning electron microscope or the like.

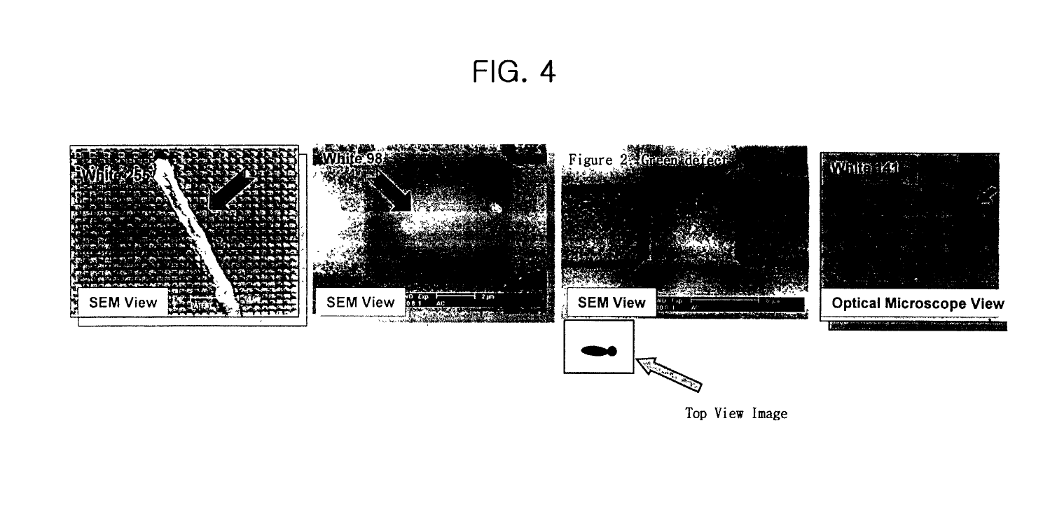

FIG. 3 is a photograph taken from the front and rear of the CFA using the sample fabricated by a method according to invention. FIG. 4 is a pictorial view showing various defects observed in accordance with the present invention. As previously mentioned, the present invention provides a method of analyzing defects arising from a plurality of photoresist-based layers formed on top of a CFA in an image sensor, thereby determining if the defect occurred from any pattern of the array and also observing a micro-defect morphology using an electron microscope. Accordingly, it is possible to precisely find out whether the defect has arisen from bottom layers or from a pattern of the array. Furthermore, the present invention provides a method of accurately analyzing the origin of a device failure so that early removal of the failure source can be made, thereby shortening a production time and enhancing reliability.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method of analyzing defects in an image sensor, comprising the steps of:
a) providing a sample wafer on a passivation layer on a substrate fabricated by a predetermined process, wherein the sample array comprises, sequentially layered, a color filter array, an overcoating layer and a micro-lens , each of which is made of photoresist material;
a) immersing the sample wafer in a hydrofluoric acid solution to etch the passivation layer and expose a back side of the color filter array; and
b) observing defects arising from the photoresist-based layers in the back side of the color filter array.

2. The method as recited in claim 1, wherein the step of observing the defects is performed using a scanning electron microscope.

3. A method of analyzing defects in an image sensor, comprising the steps of:
a) providing a sample wafer on a passivation layer of a substrate fabricated by a predetermined process, wherein the sample array comprises, sequentially layered, a color filter array, an overcoating layer and a micro-lens , each of which is made of photoresist material;
b) providing a dummy wafer having double-sided tape attached to one side;
c) pasting a surface on which the micro-lens of the sample wafer is formed on the other side of the double-sided tape;
d) immersing the sample wafer in a hydrofluoric acid solution to etch the passivation layer and expose the back side of the color filter array;
e) performing reaction ion etching from the back side of the color filter array to a defective portion; and
f) observing the defect.

4. The method as recited in claim 3, further comprising, after said step (d), the step of:
g) removing a residual or natural oxide layer from the back side of the color filter array.

5. The method as recited in claim 3, wherein the step of immersing the sample wafer in the hydrofluoric acid solution, further comprises the step of rinsing the sample wafer with acetone, and heating the acetone in order to dry the sample wafer.

6. The method as recited in claim 3, wherein the double-sided tape comprises a carbon tape.

7. The method as recited in claim 3, wherein defect observation is performed using a scanning electron microscope.
